(19) United States
(12) Patent Application Publication
(10) Pub. No.: US 2026/0239781 A1
(43) Pub. Date: Aug. 13, 2026

(54) LIGHT-EXTRACTION FILMS FOR LIGHT-EMITTING DIODE DEVICES AND RELATED METHODS

(71) Applicant: CreeLED, Inc., Durham, NC (US)

(72) Inventors: Colin Blakely, Raleigh, NC (US); David Suich, Durham, NC (US); Austin Spencer, Durham, NC (US)

(21) Appl. No.: 19/049,274

(22) Filed: Feb. 10, 2025

(51) Int. Cl. H10H 20/84; H10H 20/856; H10H 20/857

(52) U.S. Cl. CPC H10H 20/84; H10H 20/856; H10H 20/857

(57) ABSTRACT

Light-emitting diode (LED) devices and more particularly light-extraction films for LED devices and related methods are disclosed. Light-extraction films include functionalized materials with shapes, structures, and/or characteristics configured to promote increased light-extraction through light-emitting faces of LED chips. Exemplary shapes include thin films, such as generally two-dimensional films, with thicknesses that vary across light-emitting faces of LED chips. Exemplary structures include intentionally defective films that include distributions of cracks and/or voids. Exemplary characteristics include indexes of refractions that are intermediate the LED chip and encapsulants of LED packages. Related methods include forming light-extraction films after LED chip fabrication and singulation, either at the LED chip level or at the LED package level.

### FIELD OF THE DISCLOSURE

The present disclosure relates to light-emitting diode (LED) devices, and more particularly to light-extraction films for LED devices and related methods.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new applications, including LED displays, lighting devices for general illumination, and horticulture applications, among others.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials.

LED packages have been developed that can provide mechanical support, electrical connections, and encapsulation for LED emitters. As LED technology continues to be developed for ever-evolving modern applications, challenges exist in keeping up with operating demands for LED packages and related elements of LED packages.

LED technology is increasingly being developed for horticulture applications where emissions are provided to stimulate photosynthesis in growing plants. LED manufacturers for horticulture applications must balance multiple application tradeoffs of efficacy, longevity, spectral optimization, and optical distribution.

The art continues to seek improved LEDs and solid-state lighting devices having desirable illumination characteristics capable of overcoming challenges associated with conventional lighting devices.

### SUMMARY

The present disclosure relates to light-emitting diode (LED) devices, and more particularly to light-extraction films for LED devices and related methods. Light-extraction films include functionalized materials with shapes, structures, and/or characteristics configured to promote increased light extraction through light-emitting faces of LED chips. Exemplary shapes include thin films, such as generally two-dimensional films, with thicknesses that vary across light-emitting faces of LED chips. Exemplary structures include intentionally defective films that include distributions of cracks and/or voids. Exemplary characteristics include indexes of refractions that are intermediate the LED chip and encapsulants of LED packages. Related methods include forming light-extraction films after LED chip fabrication and singulation, either at the LED chip level or at the LED package level.

In one aspect, an LED package comprises: a support element; an LED chip on the support element, the LED chip forming a mounting face mounted to the support element, a light-emitting face that is opposite the mounting face, and one or more sidewalls that bound the light-emitting face and the mounting face; a light-extraction film on the light-emitting face, the light-extraction film having a thickness that is thicker proximate a middle of the LED chip than on portions of the light-emitting face that are proximate the one or more sidewalls; and an encapsulant on the light-extraction film. In certain embodiments, the thickness of the light-extraction film is in a range from 0.1 microns (μm) to 50 μm. In certain embodiments, the thickness of the light-extraction film is at least ten times thinner than a thickness of the LED chip. In certain embodiments, the light-extraction film comprises an index of refraction in a range from 1.57 to 1.80. In certain embodiments, the one or more sidewalls are devoid of the light-extraction film. In certain embodiments, the light-extraction film comprises a two-dimensional light-extraction film. In certain embodiments, the light-extraction film comprises one or more cracks and one or more voids within the light-extraction film. In certain embodiments, the LED chip is configured to generate a peak wavelength in a range from 630 nanometers (nm) to 780 nm. In certain embodiments, the LED chip is configured to generate a peak wavelength in a range from 658 nm to 665 nm. The LED package may further comprise a bond pad on the light-emitting face of the LED chip. In certain embodiments, the light-extraction film covers the bond pad and a portion of a wire bond that is connected to the bond pad. In certain embodiments, a top surface of the bond pad is devoid of the light-extraction film. The LED package may further comprise a passivation layer on the light-emitting face, wherein the light-extraction film is on the passivation layer. The LED package may further comprise a light-altering material on the support element and on the one or more sidewalls of the LED chip.

In another aspect, an LED package comprises: a support element; an LED chip on the support element, the LED chip forming a mounting face mounted to the support element, a light-emitting face that is opposite the mounting face, and one or more sidewalls that bound the light-emitting face and the mounting face; a light-altering material on the support element and on the one or more sidewalls of the LED chip; and a light-extraction film on the light-emitting face of the LED chip and on a top surface of the light-altering material. In certain embodiments, the light-extraction film covers the entire top surface of the light-altering material. In certain embodiments, the light-altering material and the light-extraction film extend to a perimeter edge of the support element. In certain embodiments, a thickness of the light-extraction film is thicker proximate a middle of the LED chip than on portions of the light-emitting face that are proximate the one or more sidewalls. The LED package may further comprise an encapsulant on the light-extraction film. In certain embodiments, the light-extraction film is positioned entirely between the light-altering material and the encapsulant. In certain embodiments, the light-altering material comprises a light-reflective material with a white color.

In another aspect, a method comprises: providing an LED chip with a mounting face, a light-emitting face that is opposite the mounting face, and one or more sidewalls that bound the light-emitting face and the mounting face; dispensing the light-extraction film on the light-emitting face; and curing the light-extraction film, the light-extraction film forming a thickness that is thicker proximate a middle of the LED chip than on portions of the light-emitting face that are proximate the one or more sidewalls. The method may further comprise: mounting the LED chip to a support element before dispensing the light-extraction film; and connecting a wire bond between the support element and a bond pad on the light-emitting face before dispensing the light-extraction film. In certain embodiments, the light-extraction film covers the bond pad and a portion of the wire bond. The method may further comprise: mounting the LED chip to a support element after dispensing the light-extraction film; and connecting a wire bond between the support element and a bond pad on the light-emitting face after dispensing the light-extraction film. In certain embodiments, a top surface of the bond pad is devoid of the light-extraction film. In certain embodiments, the thickness of the light-extraction film is in a range from 0.1 microns (μm) to 50 μm. In certain embodiments, the light-extraction film comprises an index of refraction in a range from 1.57 to 1.80. In certain embodiments, the one or more sidewalls are devoid of the light-extraction film. In certain embodiments, the LED chip is configured to generate a peak wavelength in a range from 630 nanometers (nm) to 780 nm. In certain embodiments, the light-extraction film is formed with one or more cracks and one or more voids within the light-extraction film.

In another aspect, an LED chip comprises: a mounting face, a light-emitting face that is opposite the mounting face, and one or more sidewalls that bound the light-emitting face and the mounting face; a bond pad on the mounting face; and a light-extraction film on the light-emitting face, the light-extraction film having a thickness that is thicker proximate a middle of the light-emitting face than on other portions of the light-emitting face proximate the one or more sidewalls. In certain embodiments, a top surface of the bond pad is devoid of the light-extraction film. In certain embodiments, the thickness of the light-extraction film is in a range from 0.1 microns (μm) to 50 μm. In certain embodiments, the light-extraction film comprises an index of refraction in a range from 1.57 to 1.8. In certain embodiments, the one or more sidewalls are devoid of the light-extraction film. In certain embodiments, the LED chip is configured to generate a peak wavelength in a range from 630 nanometers (nm) to 780 nm.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 is a cross-section of an exemplary light-emitting diode (LED) package according to principles of the present disclosure.

FIG. 2 is a cross-sectional view of an LED package that is similar to the LED package of FIG. 1 and further includes a light-extraction film.

FIG. 3 is a cross-sectional view of an LED package that is similar to the LED package of FIG. 2 for embodiments where the LED chip includes a passivation layer on the light-emitting face of the LED chip.

FIG. 4 is a cross-sectional view of an LED package that is similar to the LED package of FIG. 2 for embodiments where the light-extraction film does not cover the bond pad.

FIG. 5 is a cross-sectional view of an LED package that is similar to the LED package of FIG. 4 for embodiments that further include the passivation layer.

FIG. 6 is a cross-sectional view showing a defect structure of the light-extraction film for an exemplary LED package according to principles of the present disclosure.

FIG. 7A is a cross-sectional view of the LED package of FIG. 2 at a fabrication step after the LED chip is mounted to the support element.

FIG. 7B is a cross-sectional view of the LED package of FIG. 7A at a subsequent fabrication step for initial formation of the light-extraction film.

FIG. 7C is a cross-sectional view of the LED package of FIG. 7B at a subsequent fabrication step for the light-extraction film.

FIG. 7D is a cross-sectional view of the LED package of FIG. 7C after formation of the encapsulant.

FIG. 8A is a cross-sectional view of the LED package of FIG. 4 at a fabrication step after the LED chip is mounted to the support element.

FIG. 8B is a cross-sectional view of the LED package of FIG. 8A at a subsequent fabrication step for initial formation of the light-extraction film.

FIG. 8C is a cross-sectional view of the LED package of FIG. 8B at a subsequent fabrication step for the light-extraction film.

FIG. 8D is a cross-sectional view of the LED package of FIG. 8C at a subsequent fabrication step where the wire bond is formed.

FIG. 8E is a cross-sectional view of the LED package of FIG. 8D after formation of the encapsulant.

FIG. 9A is a cross-sectional view of an LED chip structure that includes the LED chip and bond pad as described with respect to FIG. 4.

FIG. 9B is a cross-sectional view of the LED chip structure of FIG. 9A at a subsequent fabrication step for initial formation of the light-extraction film.

FIG. 9C is a cross-sectional view of the LED chip structure of FIG. 9B at a subsequent fabrication step after formation of the light-extraction film is complete.

FIG. 10 is a cross-sectional view of an LED package that is similar to the LED package of FIG. 2 for embodiments that further include a light-altering material.

FIG. 11 is a cross-sectional view of an LED package that is similar to the LED package of FIG. 10 for embodiments where the light-extraction film is also on a top surface of the light-altering material.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices, and more particularly to light-extraction films for LED devices and related methods. Light-extraction films include functionalized materials with shapes, structures, and/or characteristics configured to promote increased light-extraction through light-emitting faces of LED chips. Exemplary shapes include thin films, such as generally two-dimensional films, with thicknesses that vary across light-emitting faces of LED chips. Exemplary structures include intentionally defective films that include distributions of cracks and/or voids. Exemplary characteristics include indexes of refractions that are intermediate the LED chip and encapsulants of LED packages. Related methods include forming light-extraction films after LED chip fabrication and singulation, either at the LED chip level or at the LED package level.

Before delving into specific details for aspects of the present disclosure, an overview of various elements that may be included in exemplary LED packages is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure may comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer may comprise a single quantum well, a multiple quantum well, a double heterostructure, and/or super lattice structures.

The active LED structure may be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). Other material systems include organic semiconductor materials, and other Group III-V systems such as gallium phosphide (GaP), gallium arsenide (GaAs), and related compounds such as aluminum gallium indium phosphide (AlGaInP). The active LED structure may be grown on a growth substrate that can include many materials, such as sapphire, silicon carbide (SiC), silicon, aluminum nitride (AlN), and GaN.

Different embodiments of the active LED structure may emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum (e.g., 100 nm to 400 nm), or one or more portions of the near infrared spectrum, and/or the infrared spectrum (e.g., 700 nm to 1000 nm).

In the context of horticultural applications, primary chlorophyll absorption peaks exist in certain blue and red ranges, such as a range from 450 nm to 500 nm and in another range from 630 nm to 780 nm. In certain embodiments, LED devices according to the present disclosure are well suited for use as so-called photored devices that target specific red wavelength ranges in various horticultural applications. For example, the specific red wavelength ranges may include a peak wavelength in a range of 630 nm to 780 nm, or a range from 658 nm to 665 nm.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having a different peak wavelength than the LED source. An LED source and one or more lumiphoric materials may be selected such that their combined output results in light with one or more desired characteristics such as color, color point, intensity, etc.

Lumiphoric materials as described herein may be or include one or more of a phosphor, a scintillator, a lumiphoric ink, a quantum dot material, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support structure or support element, such as a submount or a lead frame structure.

Submount structures typically include submounts with electrically conductive traces. Exemplary submount materials include ceramic materials such as aluminum oxide or alumina, AlN, or organic insulators like polyimide (PI) and polyphthalamide (PPA). In certain embodiments, submounts may comprise a printed circuit board (PCB), sapphire, Si or any other suitable material. For PCB embodiments, different PCB types can be used such as standard FR-4 PCB, metal core PCB, or any other type of PCB. Aspects of the present disclosure are also well suited for embodiments with flexible substrates. By way of example, a flexible submount may comprise a polyimide, a polyethylene terephthalate (PET), and the like with electrically conductive traces. Flexible submounts allow improved bonding in a conformal manner to other surfaces that may not be entirely planar.

Lead frame structures typically include electrically conductive leads that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The body may be formed on the lead frame structure before singulation so that the individual lead frame portions may be electrically isolated from one another and mechanically supported by the body within an individual LED package. The body may form a cup or a recess in which one or more LED chips may be mounted to the lead frame at a floor of the recess. Portions of the lead frame structure may extend from the recess and through the body to protrude or be accessible outside of the body to provide external electrical connections. An encapsulant material, such as silicone or epoxy, may fill the recess to encapsulate the one or more LED chips.

Encapsulant materials, such as silicone, epoxy, or polymethyl methacrylate (PMMA), among others, may be formed to encapsulate the LED chips over a submount or a lead frame structure. In certain embodiments, one or more lumiphoric materials, such as phosphor particles, may be integrated or otherwise embedded within the encapsulant material. Moreover, encapsulant materials may be shaped to form single lens structures and/or multiple lens structures in a single LED package.

Light-altering materials may be arranged within LED packages, such as along submount surfaces, to reflect or otherwise redirect light from the one or more LED chips in a desired emission direction or pattern. As used herein, light-altering materials may include many different materials including light-reflective materials that reflect or redirect light, light-absorbing materials that absorb light, and materials that act as a thixotropic agent. As used herein, the term “light-reflective” refers to materials or particles that reflect, refract, scatter, or otherwise redirect light. For light-reflective materials, the light-altering material may include at least one of fused silica, fumed silica, titanium dioxide (TiO₂), or metal particles suspended in a binder, such as silicone or epoxy. For light-absorbing materials, the light-altering material may include at least one of carbon, silicon, or metal particles suspended in a binder, such as silicone or epoxy. The light-reflective materials and the light-absorbing materials may comprise nanoparticles. In certain embodiments, the light-altering material may comprise a generally white color to reflect and redirect light. In other embodiments, the light-altering material may comprise a generally opaque color, such as black or gray for absorbing light and increasing contrast. In certain embodiments, the light-altering material includes both light-reflective material and light-absorbing material suspended in a binder.

Challenges exist in operating LED devices at higher light emission efficiencies, which may be measured by the emission intensity in relation to the output power (e.g., in lumens per watt). A practical goal to enhance emission efficiency is to increase extraction of light emitted by the active region in the direction of the desired transmission of light. Light extraction and external quantum efficiency of an LED can be limited by a number of factors, including internal reflection. Photons reaching interfaces with refractive index steps, such as between an LED surface and an encapsulant, may be either refracted or internally reflected. If photons are internally reflected in a repeated manner, then such photons eventually are absorbed and never provide visible light that exits an LED.

According to aspects of the present disclosure, improved light-extraction films are formed on a light-emitting surface of an LED chip. In certain embodiments, the light-extraction film may embody a functionalized silicone-based resin for enhanced light-extraction in LED packages with encapsulants and associated lenses. In addition to functionalized silicones, other materials include functionalized acrylate-based polymers, and/or composites of polymers with a distribution of metal oxide nano-particles. In certain embodiments, light-extraction films are formed with thicknesses that are at least ten times thinner than a thickness of the underlying LED chip. In one example, an exemplary LED chip may have a thickness of 220 microns (μm) and the light-extraction film is provided with a thickness that does not exceed 20 μm. In certain embodiments, the thickness of the light-extraction film is in a range from 0.1 μm to 50 μm, or 0.1 μm to 40 μm, or 0.1 μm to 20 μm. By forming the light-extraction film so thin, the light-extraction film will generally form with a two-dimensional structure that is compressed with various defects, such as internal cracks, voids, and/or increased porosity. Such defects may be beneficial in forming additional scattering sites for increased light extraction through the light-extraction film.

Moreover, maintaining such a thin and generally two-dimensional structure provides an increased index of refraction for the light-extraction film as compared to thicker and more three-dimensional films of even the same material. For example, an index of refraction of a light-extraction film according to the present disclosure may be at least 1.60, or in a range from 1.60 to 1.66, or 1.64 in certain embodiments. In certain embodiments, index of refraction of the light-extraction film is in a range from 1.57 to 1.80. While the principles of the present disclosure are useful for LED chips emitting any wavelength, certain aspects are particularly useful for red LED chips that may include epitaxial structures, such as AlGaInP or other epitaxial structures based on gallium phosphide or gallium arsenide materials and alloys. Based on these material types, the epitaxial structures for certain red LED chips may have an index of refraction that is relatively high, such as 3 or above in certain embodiments. Common silicone encapsulants for LED packages may have index of refractions in a range from 1.41 to 1.54. By positioning the higher refractive index of the light-extraction film at a light-emitting face of the LED chip, increased light may escape the LED chip before reaching an interface with the encapsulant. As mentioned above, the defective nature of the light-extraction film may further enhance light-extraction.

Light-extraction films according to the present disclosure may be formed after LED chips have completed fabrication and been singulated. In this regard, the light-extraction films may be formed with distinct properties compared with various passivation layers formed during LED chip fabrication. The light-extraction films may be formed by dispensing an amount of material on the fully-formed and singulated LED chip, allowing the dispensed material to laterally spread across the light-emitting face, followed by curing in place. In this regard, the light-extraction films may be formed with variable thicknesses, such as thicker in a middle portion of the film and thinner proximate sidewalls or perimeter edges of the LED chip. Such a structure may be beneficial for shaping light-extraction and/or light-emission patterns of the LED chip. Moreover, the ability to form the light-extraction film after complete fabrication of the LED chip permits LED package manufacturers to selectively alter increases in light-emissions and/or light-emission patterns or viewing angles on a chip-by-chip basis. This may be accomplished by altering a thickness or a material of the light-extraction film alone or in combination with selecting different encapsulant materials with different index of refractions.

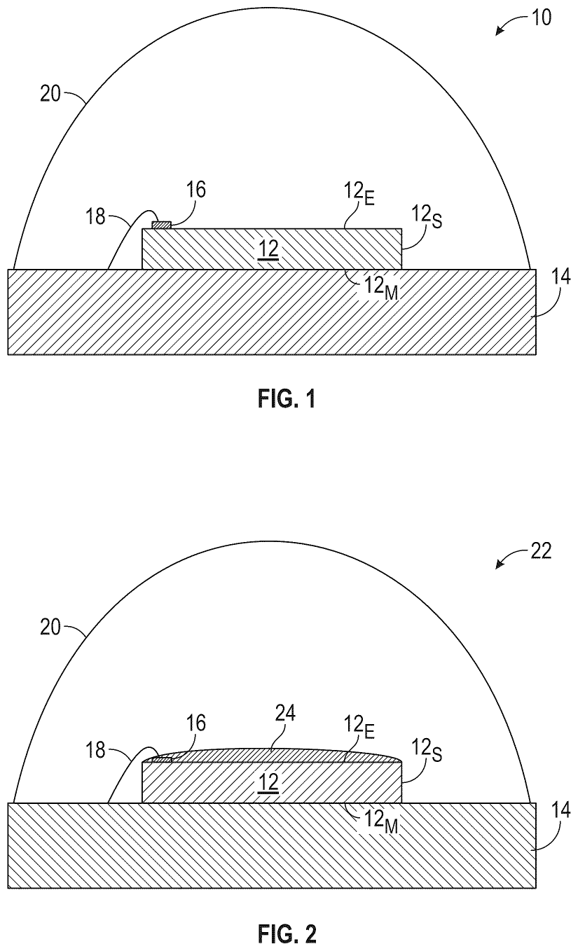

FIG. 1 is a cross-section of an exemplary LED package 10 according to principles of the present disclosure. The LED package 10 includes an LED chip 12 mounted to a support element 14. In certain embodiments, the support element 14 may embody a submount or a lead frame structure. The LED chip 12 forms a mounting face 12_{M} mounted to the support element 14, a light-emitting face 12_{E} that is opposite the mounting face 12_{M}, and one or more sidewalls 12_{S} that bound the light-emitting face 12_{E} and the mounting face 12_{M}. The light-emitting face 12_{E} may also be referred to as a top face of the LED chip 12. While some light may escape the sidewalls 12_{S}, the light-emitting face 12_{E} forms the primary light-emitting face where most of the light from the LED chip 12 is emitted. In the example of FIG. 1., the LED chip 12 has a vertical contact structure where a bond pad 16 is formed on the light-emitting face 12_{E} to form a first contact and another contact is formed on the mounting face 12_{M} at the interface with the support element 14. By way of example, the bond pad 16 may form a cathode contact on the light-emitting face 12_{E} that may be electrically connected by way of a wire bond 18, and an anode contact is formed at the interface between the mounting face 12_{M} and the support element 14. Another end of the wire bond 18 may be bonded to a different portion of the support element 14 than the mounting face 12_{M}, such as to a different electrically conductive trace than the mounting face 12_{M}. An encapsulant 20 is provided on the LED chip 12 and the support element 14. The encapsulant 20 may comprise silicone or epoxy and may be formed in the shape of a lens, such as having a curved exterior surface. The lens may form various shapes, including but not limited to, a square or rectangular cubic shape, a hemispherical-shaped lens, a hemispherical-shaped lens with planar side surfaces, an oval shaped lens, or a cylindrical shaped lens with a curved top surface, among others. As described above, an increased index of refraction step between the material of the LED chip 12 and the encapsulant 20 may result in some light loss due to internal reflection, particularly in red LED chips, such as those configured to generate peak wavelengths in a range from 630 to 780 nm, or in a range from 658 nm to 665 nm.

FIG. 2 is a cross-sectional view of an LED package 22 that is similar to the LED package 10 of FIG. 1 and further includes a light-extraction film 24. It is understood the description of like-numbered elements from FIG. 1 are equally applicable to FIG. 2. As illustrated in FIG. 2, the light-extraction film 24 is formed on the light-emitting face 12_{E}. In certain embodiments, the light-extraction film 24 covers the bond pad 16 and at least a portion of the wire bond 18. In this regard, the light-extraction film 24 may be formed after the LED chip 12 is mounted to the support element 14 and after the wire bond 18 is connected. While not drawn to scale for illustrative purposes, a thickness of the light-extraction film is at least 10 times thinner than a thickness of the LED chip 12 as measured in a direction perpendicular to the top surface of the support element 14 at in interface with the mounting face 12_{M} of the LED chip 12. As described above, exemplary thicknesses for the light-extraction film 24 may not exceed 20 μm in certain embodiments. Moreover, the thickness of the light-extraction film 24 may vary across the light-emitting face 12_{E}. For example, the thickness of the light-extraction film 24 may be thicker proximate a middle of the LED chip 12 than on portions of the light-emitting face 12_{E} that are proximate the one or more sidewalls 12_{S}. This may provide a generally curved outer surface of the light-extraction film 24 for tailoring light emissions. In certain embodiments, the light-extraction film 24 is formed such that it is confined to the light-emitting face 12_{E}, and the sidewalls 12_{S} are devoid of the light-extraction film 24. This may permit the light-extraction film 24 to remain a continuous structure without breaks or larger discontinuities that could form at corners with the sidewalls 12_{S} if attempting to conform the light-extraction film 24 along the sidewalls 12_{S}. Such larger discontinuities could disrupt the structure of the light-extraction film 24 and reduce light-extraction efficacy by altering the index of refraction.

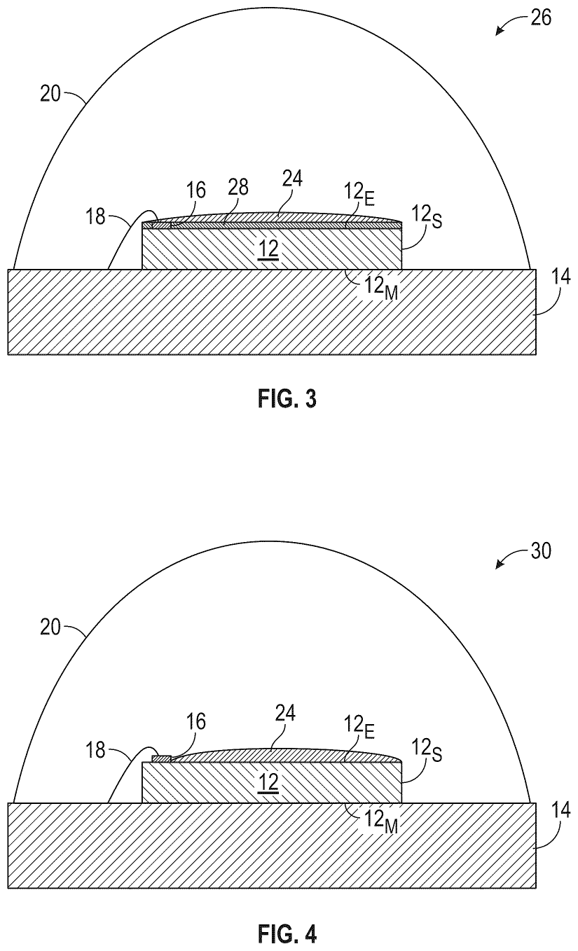

FIG. 3 is a cross-sectional view of an LED package 26 that is similar to the LED package 22 of FIG. 2 for embodiments where the LED chip 12 includes a passivation layer 28 on the light-emitting face 12_{E} of the LED chip 12. In certain embodiments, the passivation layer 28 is included as part of the fabrication of the LED chip 12. For example, the passivation layer 28 may be formed at a wafer level as part of a fabrication stack before singulation of the individual LED chip 12. In this manner, the passivation layer 28 is integrated as part of the LED chip 12 and may include one or more layers of dielectric materials, such as silicon nitride or silicon dioxide. In contrast to the light-extraction film 24, the passivation layer 28 may form with a substantially uniform thickness with a same chemical composition throughout and may lack the defect structure of the light-extraction film 24. As illustrated, the light-extraction film 24 may be formed on the passivation layer 28, thereby providing improved light-extraction as compared to the passivation layer 28.

FIG. 4 is a cross-sectional view of an LED package 30 that is similar to the LED package 22 of FIG. 2 for embodiments where the light-extraction film 24 does not cover the bond pad 16. In certain embodiments, the light-extraction film 24 may be formed in a manner that terminates at the bond pad 16 or with some tolerance away from the bond pad 16. Accordingly, a top surface of the bond pad 16 is devoid of the light-extraction film 24. Such an arrangement may be useful for embodiments where the light-extraction film 24 is formed on the LED chip 12 before the wire bond 18 is connected. This may occur before or after the LED chip 12 is mounted to the support element 14. For embodiments where the light-extraction film 24 is formed before mounting to the support element 14, the light-extraction film 24 may be formed as part of the LED chip 12, but still after singulation of the LED chip 12 from the wafer level. In certain embodiments, the light-extraction film 24 is formed to contact perimeter edges of the bond pad 16 while leaving the top surface uncovered to receive the wire bond 18.

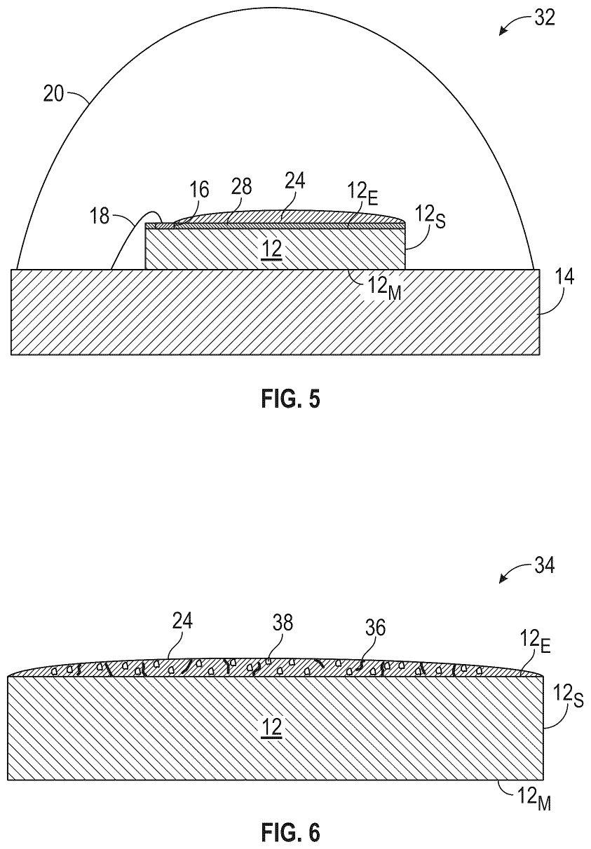

FIG. 5 is a cross-sectional view of an LED package 32 that is similar to the LED package 30 of FIG. 4 for embodiments that further include the passivation layer 28. The passivation layer 28 may be formed as described above with respect to FIG. 3. In FIG. 5, the light-extraction film 24 may cover portions of the passivation layer 28 while other portions of the passivation layer 28 may be uncovered proximate the bond pad 16. As with FIG. 4, a top surface of the bond pad 16 may be uncovered or devoid of the light-extraction film 24.

FIG. 6 is a cross-sectional view showing a defect structure of the light-extraction film 24 for an exemplary LED package 34 according to principles of the present disclosure. The LED package 34 may embody any of the LED packages described above with respect to FIGS. 2 to 5, and the structure of the light-extraction film 24 is applicable to all of the light-extraction films 24 of FIGS. 2 to 5. For illustrative purposes, only the LED chip 12 and the light-extraction film 24 are shown in FIG. 6. As illustrated, the light-extraction film 24 is formed with a number of defects, including a number of cracks 36 and/or voids 38. The cracks 36 may extend partially through the light-extraction film 24 and the voids 38 may be embedded within the light-extraction film 24. Accordingly, the light-extraction film 24 may be formed with an intentionally defective and porous structure as compared with the conventional passivation layer 28 of FIGS. 3 and 5. Moreover, the light-extraction film 24 may be formed with the varying thickness from a center of the LED chip to the sidewalls 12_{S}.

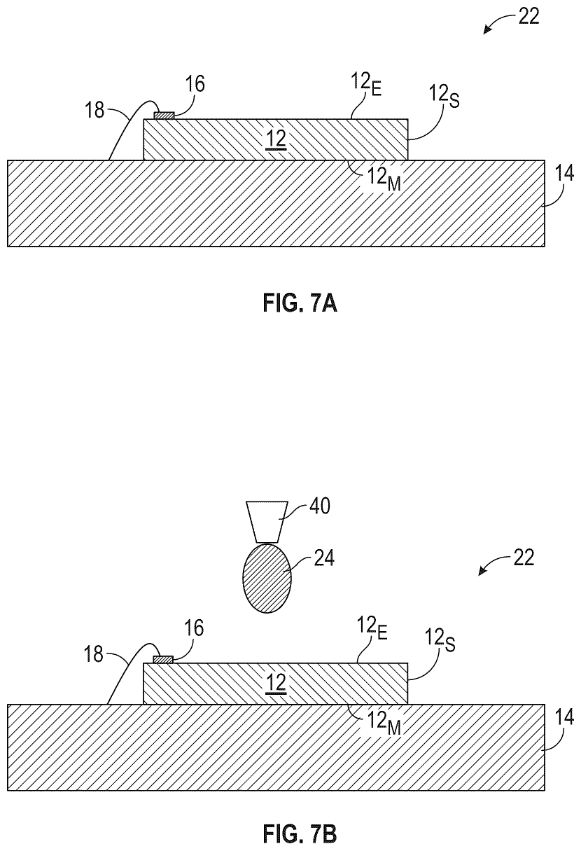

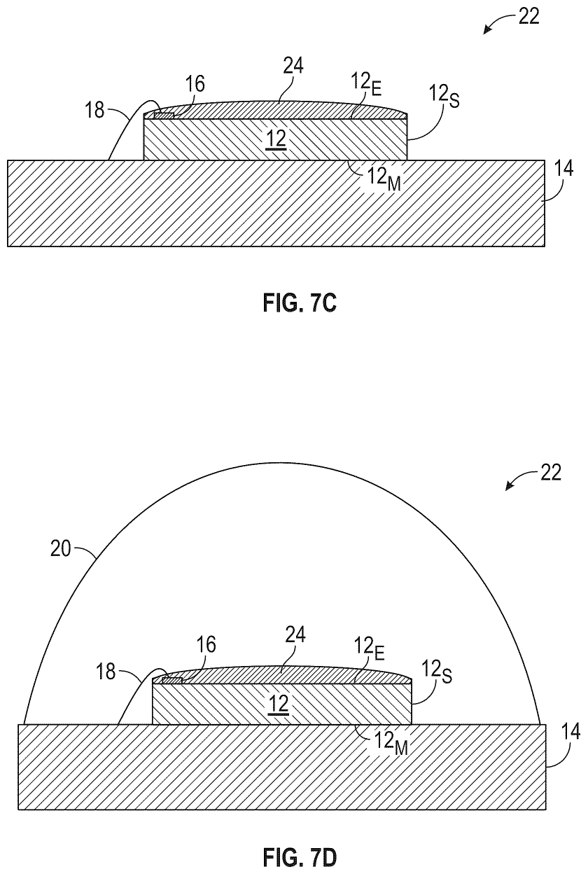

FIGS. 7A to 7D illustrate a fabrication sequence for forming the LED package 22 of FIG. 2 where the light-extraction film 24 is formed after the LED chip 12 is mounted to the support element 14.

FIG. 7A is a cross-sectional view of the LED package 22 of FIG. 2 at a fabrication step after the LED chip 12 is mounted to the support element 14. Additionally, the wire bond 18 may be subsequently connected to the bond pad 16.

FIG. 7B is a cross-sectional view of the LED package 22 of FIG. 7A at a subsequent fabrication step for initial formation of the light-extraction film 24. In certain embodiments, the material of the light-extraction film 24 may be applied or otherwise dispensed on the LED chip 12 by way of a nozzle 40. The material of the light-extraction film 24 may be applied in greater concentrations along a center portion of the light-emitting face 12_{E} and allowed to spread and/or wick towards the sidewalls 12_{S}.

FIG. 7C is a cross-sectional view of the LED package 22 of FIG. 7B at a subsequent fabrication step for the light-extraction film 24. After the material of the light-extraction film 24 is permitted to spread and/or wick along the light-emitting face 12_{E} to an intended position, a heating step is applied to cure the light-extraction film 24 and its corresponding shape in place.

FIG. 7D is a cross-sectional view of the LED package 22 of FIG. 7C after formation of the encapsulant 20. The encapsulant 20 may be molded on the support element 14 and over the LED chip 12. Accordingly, the encapsulant 20 may form encapsulation for the LED chip 12 while also providing a lens shape for a desired light emission pattern. As described above, a refractive index of the encapsulant 20 and/or a shape of the lens may be selected in combination with the refractive index and/or shape of the light-extraction film 24 to tailor emission patterns for different applications.

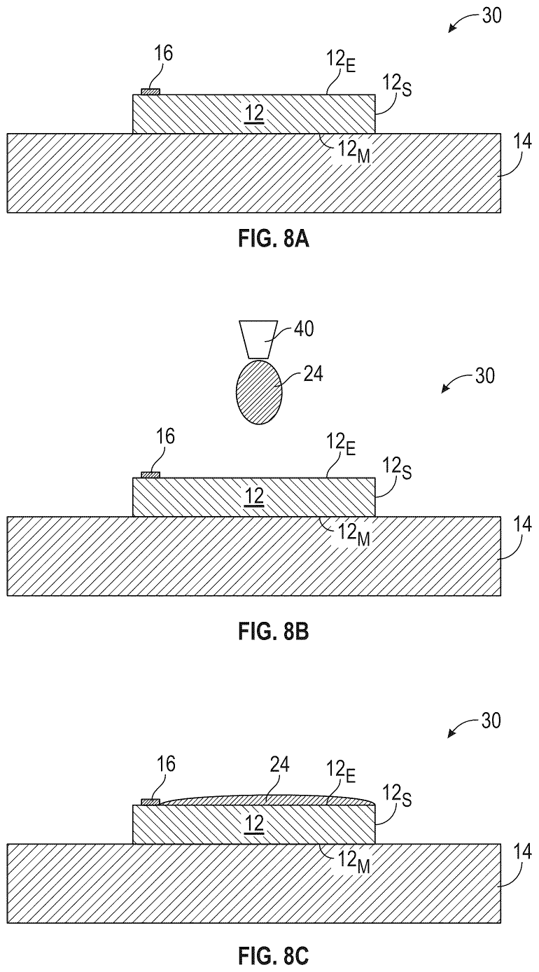

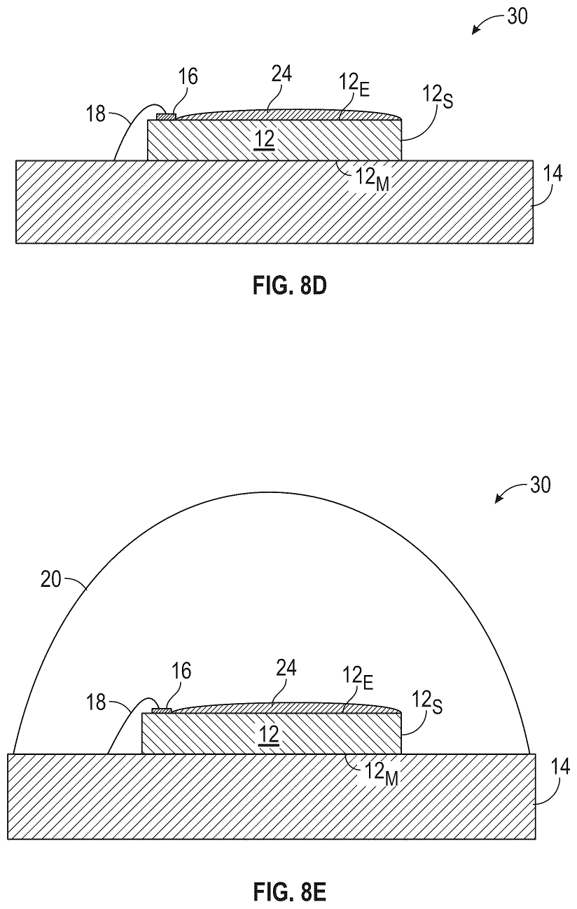

FIGS. 8A to 8E illustrate a fabrication sequence for forming the LED package 30 of FIG. 4 where the light-extraction film 24 does not cover a top surface of the bond pad 16.

FIG. 8A is a cross-sectional view of the LED package 30 of FIG. 4 at a fabrication step after the LED chip 12 is mounted to the support element 14. As illustrated, the wire bond 18 of FIG. 4 is not yet connected to the bond pad 16.

FIG. 8B is a cross-sectional view of the LED package 30 of FIG. 8A at a subsequent fabrication step for initial formation of the light-extraction film 24. In a similar manner as described above for FIG. 7B, the material of the light-extraction film 24 may be applied or otherwise dispensed on the LED chip 12 by way of the nozzle 40. The material of the light-extraction film 24 may be applied in greater concentrations along a center portion of the light-emitting face 12_{E} and allowed to spread and/or wick towards the sidewalls 12_{S} and toward perimeter edges of the bond pad 16.

FIG. 8C is a cross-sectional view of the LED package 30 of FIG. 8B at a subsequent fabrication step for the light-extraction film 24. After the material of the light-extraction film 24 is permitted to spread and/or wick along the light-emitting face 12_{E}, a heating step is applied to cure the light-extraction film 24 and its corresponding shape in place. As illustrated, the top surface of the bond pad 16 is devoid of the light-extraction film 24. In certain embodiments, the light-extraction film 24 contacts perimeter edges of the bond pad 16 while leaving the top surface uncovered to receive a wire bond.

FIG. 8D is a cross-sectional view of the LED package 30 of FIG. 8C at a subsequent fabrication step where the wire bond 18 is formed. After the light-extraction film 24 is cured in place, the wire bond 18 may then be connected to the bond pad 16 in the area that is uncovered by the light-extraction film 24.

FIG. 8E is a cross-sectional view of the LED package 30 of FIG. 8D after formation of the encapsulant 20. The encapsulant 20 may be molded on the support element 14 and over the LED chip 12. Accordingly, the encapsulant 20 may form encapsulation for the LED chip 12 while also providing a lens shape for a desired light emission pattern. As described above, a refractive index of the encapsulant 20 and/or a shape of the lens may be selected in combination with the refractive index and/or shape of the light-extraction film 24 to tailor emission patterns for different applications.

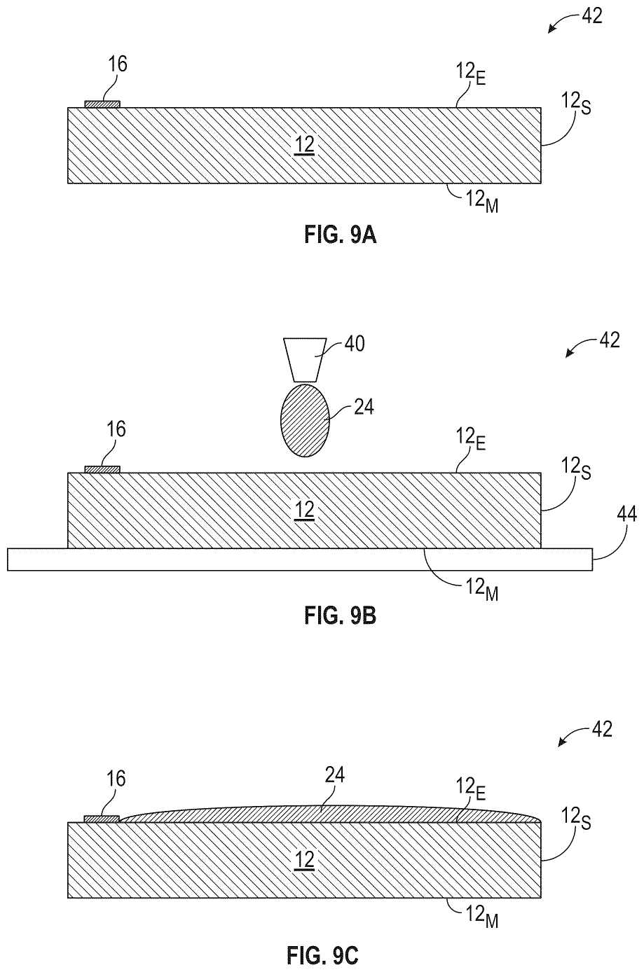

As described above with respect to FIGS. 8A to 8E, the light-extraction film 24 may be formed before the wire bond 18 is connected to the bond pad 16. In certain embodiments, the principles described above for dispensing and curing the light-extraction film 24 may be performed at the LED chip level rather than the LED package level. FIGS. 9A to 9C illustrate an LED chip-level fabrication sequence.

FIG. 9A is a cross-sectional view of an LED chip structure 42 that includes the LED chip 12 and bond pad 16 as described with respect to FIG. 4. The LED chip 12 may be fabricated at a wafer level through a combination of epitaxial growth steps and post-growth fabrication steps to form the bond pad 16 and any optional passivation layers. After wafer level fabrication, singulation provides individual ones of the LED chip structure 42 of FIG. 9A as a stand alone structure.

FIG. 9B is a cross-sectional view of the LED chip structure 42 of FIG. 9A at a subsequent fabrication step for initial formation of the light-extraction film 24. In certain embodiments, the LED chip 12 may be attached to a temporary carrier 44 that facilitates formation of the light-extraction film 24. The material of the light-extraction film 24 may be dispensed or otherwise applied by way of the nozzle 40 in a similar manner described above for FIGS. 7B and 8B.

FIG. 9C is a cross-sectional view of the LED chip structure 42 of FIG. 9B at a subsequent fabrication step after formation of the light-extraction film 24 is complete. For example, the light-extraction film 24 is permitted to spread and/or wick along the light-emitting face 12_{E}, and a heating step is applied to cure the light-extraction film 24 and its corresponding shape in place in a similar manner as described above for FIGS. 7C and 8C. In certain embodiments, the top surface of the bond pad 16 is devoid or uncovered by the light-extraction film 24. Additionally, the temporary carrier 44 of FIG. 9B may be removed to provide the completed LED chip structure 42. In certain embodiments, the LED chip structure 42 may be referred to as an LED chip that includes the integrated light-extraction film 24. Accordingly, the LED chip structure 42 may embody an LED chip with an integrated light-extraction film 24 that is ready to be mounted in an LED package.

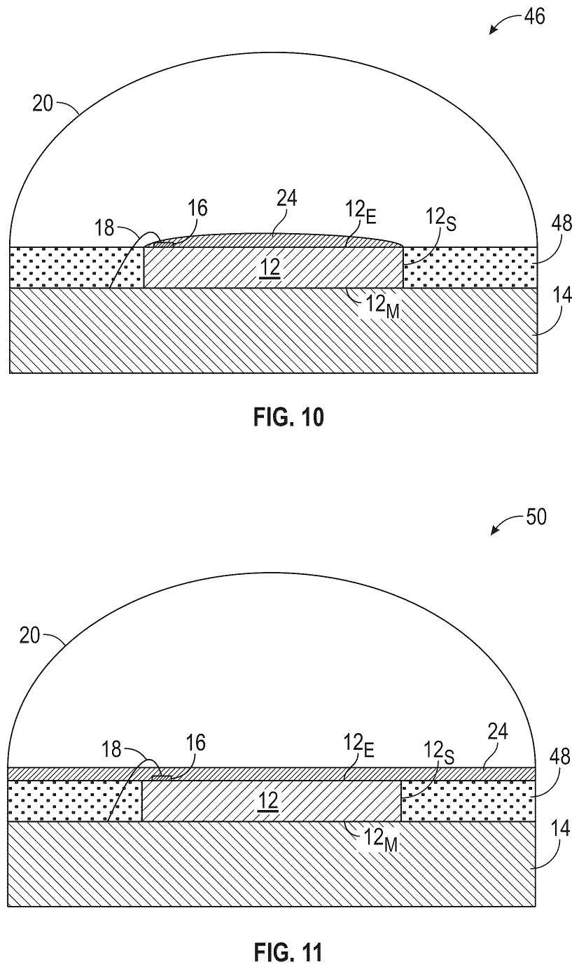

FIG. 10 is a cross-sectional view of an LED package 46 that is similar to the LED package 22 of FIG. 2 for embodiments that further include a light-altering material 48. The light-altering material 48 may embody a light-reflective material, such as having a white color or appearance, that is formed on the support element 14 and on the one or more sidewalls 12_{S} of the LED chip 12. The light-altering material 48 is positioned to redirect laterally propagating light toward the light-emitting face 12_{E} in an intended light-emission direction. The light then passes through the light-extraction film 24 with increased light extraction into the encapsulant 20, before exiting the LED package 46. In certain embodiments, the light-altering material 48 at least partially covers the top surface of the support element 14, and in further embodiments, the light-altering material 48 extends all the way to a perimeter edge of the support element 14.

FIG. 11 is a cross-sectional view of an LED package 50 that is similar to the LED package 46 of FIG. 10 for embodiments where the light-extraction film 24 is also on a top surface of the light-altering material 48. As illustrated, the light-extraction film 24 is positioned to extend on the top surface of the light-altering material 48 in a direction away from the LED chip 12. In certain embodiments, the light-extraction film 24 covers the entire top surface of the light-altering material 48. In such an arrangement, the light-extraction film 24 is positioned entirely between the encapsulant 20 and the light-altering material 48 so that the high refractive index material of the light-extraction film 24 is positioned at interfaces with the encapsulant 20. In still further embodiments, the light-altering material 48 and the light-extraction film 24 extend to the perimeter edge of the support element 14 such that the entire top surface of the support element 14 outside the LED chip 12 is covered. As illustrated, the wire bond 18 may extend through both the light-extraction film 24 and the light-altering material 48. In certain embodiments, the hardness of the light-altering material 48 is less than a hardness of the light-extraction film 24. As such, the light-altering material 48 may provide stress relief for the portion of the wire bond 18 that is bonded to the support element 14, while another portion of the wire bond 18 is partially encapsulated by the harder material of the light-extraction film 24. As with other embodiments, the light-extraction film 24 of FIG. 11 may be formed with a thickness that is thicker proximate a middle of the LED chip 12 than on portions of the light-emitting face 12_{E} that are proximate the one or more sidewalls 12_{S}. In other embodiments, the light-extraction film 24 may be formed in a more uniform manner across the LED chip 12 and the light-altering material 48.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

1. A light-emitting diode (LED) package comprising:
a support element;
an LED chip on the support element, the LED chip forming a mounting face mounted to the support element, a light-emitting face that is opposite the mounting face, and one or more sidewalls that bound the light-emitting face and the mounting face;
a light-extraction film on the light-emitting face, the light-extraction film having a thickness that is thicker proximate a middle of the LED chip than on portions of the light-emitting face that are proximate the one or more sidewalls; and
an encapsulant on the light-extraction film.

2. The LED package of claim 1, wherein the thickness of the light-extraction film is in a range from 0.1 microns (μm) to 50 μm.

3. The LED package of claim 1, wherein the thickness of the light-extraction film is at least ten times thinner than a thickness of the LED chip.

4. The LED package of claim 1, wherein the light-extraction film comprises an index of refraction in a range from 1.57 to 1.80.

5. The LED package of claim 1, wherein the one or more sidewalls are devoid of the light-extraction film.

6. The LED package of claim 1, wherein the light-extraction film comprises a two-dimensional light-extraction film.

7. The LED package of claim 1, wherein the light-extraction film comprises one or more cracks and one or more voids within the light-extraction film.

8. The LED package of claim 1, wherein the LED chip is configured to generate a peak wavelength in a range from 630 nanometers (nm) to 780 nm.

9. The LED package of claim 8, wherein the LED chip is configured to generate a peak wavelength in a range from 658 nm to 665 nm.

10. The LED package of claim 1, further comprising a bond pad on the light-emitting face of the LED chip.

11. The LED package of claim 10, wherein the light-extraction film covers the bond pad and a portion of a wire bond that is connected to the bond pad.

12. The LED package of claim 10, wherein a top surface of the bond pad is devoid of the light-extraction film.

13. The LED package of claim 1, further comprising a passivation layer on the light-emitting face, wherein the light-extraction film is on the passivation layer.

14. The LED package of claim 1, further comprising a light-altering material on the support element and on the one or more sidewalls of the LED chip.

15. A light-emitting diode (LED) package comprising:
a support element;
an LED chip on the support element, the LED chip forming a mounting face mounted to the support element, a light-emitting face that is opposite the mounting face, and one or more sidewalls that bound the light-emitting face and the mounting face;
a light-altering material on the support element and on the one or more sidewalls of the LED chip; and
a light-extraction film on the light-emitting face of the LED chip and on a top surface of the light-altering material.

16. The LED package of claim 15, wherein the light-extraction film covers the entire top surface of the light-altering material.

17. The LED package of claim 15, wherein the light-altering material and the light-extraction film extend to a perimeter edge of the support element.

18. The LED package of claim 15, wherein a thickness of the light-extraction film is thicker proximate a middle of the LED chip than on portions of the light-emitting face that are proximate the one or more sidewalls.

19. The LED package of claim 15, further comprising an encapsulant on the light-extraction film.

20. The LED package of claim 19, wherein the light-extraction film is positioned entirely between the light-altering material and the encapsulant.

21. The LED package of claim 15, wherein the light-altering material comprises a light-reflective material with a white color.

22-37. (canceled)
